(19) United States
(12) Patent Application Publication
(10) Pub. No.: US 2007/0253179 A1
(43) Pub. Date: Nov. 1, 2007

(54) Method and apparatus for removing surface mount device from printed circuit board

(76) Inventor: Randall Don Briggs, Boise, ID (US)

Correspondence Address: BRINKS HOFER GILSON & LIONE/MARVELL, P.O. BOX 10395, CHICAGO, IL, 60610, US

(21) Appl. No.: 11/412,467

(22) Filed: Apr. 27, 2006

(51) Int. Cl. H05K 7/12; H05K 7/10

(52) U.S. Cl. 361/808

(57) ABSTRACT

Disclosed are various embodiments of, and accompanying methods relating to, one or more weakened zones provided inside a surface mount device perimeter of a printed circuit board. The one or more weakened zones facilitate removal of a surface mount device from the printed circuit board after the surface mount device has been attached to the printed circuit board with an adhesive. The devices and methods disclosed herein may also be employed when the surface mount device has not only been attached to a printed circuit by an adhesive but also by solder connecting the contacts or leads of the surface mount device to corresponding pads located on the printed circuit board.

### FIELD OF THE INVENTION

The present invention relates to printed circuit board manufacturing, repair and modification, and to removing surface mount devices from printed circuit boards.

### BACKGROUND

In a manufacturing process well known in the art of attaching surface mount devices (SMDs) to printed circuit boards (PCBs) called “solder reflow,” an SMD such as a Quad Flat Pack (QFP) IC package is soldered to a printed circuit board (PCB). Contacts disposed on the SMD are soldered onto corresponding pads disposed on the PCB that have been previously coated with solder paste. When located on the top side of the PCB, the force of gravity generally keeps an SMD in place while a PCB is heated to melt the solder and attach the SMD to the PCB.

If, however, during the heating process the PCB is oriented such that the SMD is located upside down on the bottom side of the PCB, the SMD will fall off the PCB during heating unless the SMD has first been glued to the PCB. Thereafter the SMD may be soldered to the PCB. Glue is often used in such a fashion when an SMD is to be mounted on a double-sided PCB or when a wave-solder process is employed rather than a standard solder reflow process.

There arise situations where it becomes necessary to remove an SMD from a PCB after soldering. One such situation may arise during production manufacturing where testing reveals that an SMD is defective and must be replaced. Another such situation may arise in a post-manufacturing scenario where a PCB fails in the field and is returned to the manufacturer, vendor or supplier for failure analysis. Yet another such situation may arise during IC package qualification towards the end of a PCB manufacturing process, where an SMD is removed from a PCB to determine how tolerant the SMD is to stresses induced by wave soldering. Still other circumstances arise where SMDs that have been glued and soldered to PCBs need to be removed from a PCB.

In the context of removing a soldered and glued SMD from a PCB, removing solder bonding the contacts of the SMD to PCB pads may be accomplished rather easily using well-known solder reflow and heating techniques. The glue attaching an SMD to a PCB is another matter, however. One known method of breaking the adhesive bond between an SMD AND A PCB is to remove all solder from the SMD contacts and PCB pads and then heat the glue to weaken the bond. Thereafter, the SMD may be removed from the PCB by striking, hitting, tapping or otherwise applying a suitable mechanical force to the SMD to break the adhesive bond. If the glue is heat-resistant or of a high-temperature variety, however, heating the adhesive bond may result in the adhesive bond not breaking. Additionally, striking, hitting or tweaking the SMD after the glue bond has been heated may result in damage to the SMD, in which case the object of removing the SMD in the first place may be completely thwarted (e.g., when the SMD has been removed for purposes of failure analysis or IC package qualification).

Various patents containing subject matter relating directly or indirectly to the field of the present invention include, but are not limited to, the following:

U.S. Pat. No. 4,270,260 for Method for the salvage and restoration of integrated circuits from a substrate to Krueger.

U.S. Pat. No. 4,569,473 for Apparatus for and method of desoldering and removing an integrated circuit from a mounting member and for cleaning the same to Guiliano.

U.S. Pat. No. 4,588,468 for Apparatus for changing and repairing printed circuit boards to McGinty et al.

U.S. Pat. No. 4,659,004 for Device for attaching modular electronic components to or removing them from an insulative device to Fridman.

U.S. Pat. No. 4,752,025 for Surface mount assembly repair terminal to Stach et al.

U.S. Pat. No. 4,767,047 for Desoldering device to Todd et al.

U.S. Pat. No. 5,148,969 for Component reclamation apparatus and method to Boucher et al.

U.S. Pat. No. 5,553,766 for In-situ device removal for multi-chip modules to Jackson et al.

U.S. Pat. No. 5,598,965 for Integrated circuit, electronic component chip removal and replacement system to Scheu.

U.S. Pat. No. 5,707,000 Apparatus and method for removing known good die using hot shear process to Olson et al.

U.S. Pat. No. 6,360,934 Apparatus and method for removing a soldered device from a printed circuit board to Cilia et al.

U.S. Pat. No. 6,651,322 for Method of reworking a multilayer printed circuit board assembly to Currie.

U.S. Pat. No. 6,942,137 for Die removal method and apparatus to Bolde et al.

What is needed is a method and apparatus that permits an SMD to be glued to a PCB and thereafter removed without damaging the SMD or altering the characteristics of the SMD during the soldering process, as well as a device and method that does not add significantly to the cost or complexity of the PCB manufacturing process. Upon having read and understood the Summary, Detailed Descriptions and Claims set forth below, those skilled in the art will appreciate that at least some of the methods and apparatus disclosed in the printed publications listed herein may be modified advantageously in accordance with the teachings of the present invention.

### SUMMARY

In a first embodiment of the present invention, there is provided a printed circuit board comprising a plurality of pads configured to receive surface mount device contacts thereon. The pads define a surface mount device perimeter for each surface mount device that is to be mounted on the circuit board. One or more weakened zones are positioned inside the perimeter and are configured to facilitate removal of the surface mount device from the board after the surface mount device has been attached to the board with an adhesive. The one or more weakened zones may comprise, alone or in combination, one or more through-holes, through-slots, or thinned portions. The first embodiment of the present invention may also include a surface mount device and/or an adhesive disposed between the surface mount device and the printed circuit board.

In a second embodiment of the present invention, there is provided a printed circuit board having a plurality of electronic components mounted thereon, and comprising a plurality of pads configured to receive surface mount device contacts thereon. The pads for each surface mount device that is to be mounted on the board define a surface mount device perimeter on the circuit board. One or more weakened zones are positioned inside the perimeter and are configured to facilitate removal of the surface mount device from the board after the surface mount device has been attached to the board with an adhesive. The one or more weakened zones may comprise, alone or in combination, one or more through-holes, through-slots or thinned portions. The second embodiment of the present invention may also include a surface mount device and/or an adhesive disposed between the surface mount device and the printed circuit board.

In a third embodiment of the present invention, there is provided an electronic device comprising a printed circuit board having a plurality of electronic components mounted thereon, and comprising a plurality of pads configured to receive surface mount device contacts thereon. The pads define a surface mount device perimeter for each surface mount device that is to be mounted on the printed circuit board. One or more weakened zones are positioned inside the perimeter and are configured to facilitate removal of the surface mount device from the board after the surface mount device has been attached to the board with an adhesive. The one or more weakened zones may comprise, alone or in combination, one or more through-holes, through-slots or thinned portions. The third embodiment of the present invention may also include a surface mount device and/or an adhesive disposed between the surface mount device and the printed circuit board.

In a fourth embodiment of the present invention, there is provided a method of forming weakened zones in a printed circuit board to facilitate removal of a surface mount device glued to the board, where the method comprises providing the printed circuit board and forming one or more weakened zones in the printed circuit board inside a surface mount device perimeter corresponding to each surface mount device that is to be mounted on the printed circuit board. The method may further comprise one or more of forming one or more through-holes, forming one or more through-slots and forming one or more thinned portions, providing the surface mount device, dispensing an adhesive onto the printed circuit board, placing the surface mount device on the adhesive, curing the adhesive, and/or soldering the surface mount device to the printed circuit board.

In a fifth embodiment of the present invention, there is provided a method of facilitating removal of a surface mount device that has been glued and soldered to a printed circuit board, where the printed circuit board comprises one or more weakened zones located inside a surface mount perimeter corresponding approximately to the outlines of each surface mount device that is to be mounted on the printed circuit board. The method of the fifth embodiment comprises removing solder connecting surface mount device contacts to pads located on the printed circuit board and at least one of abrading, cutting, scribing, drilling, sawing, scoring, cutting, laser cutting or weakening, laser etching, applying one or more chemical solvents, applying one or more suitable chemical catalysts, treating and etching the weakened zones of the printed circuit board to facilitate release of the surface mount device from the printed circuit board. The method of the fifth embodiment of the present invention may further comprise removing the surface mount device from the printed circuit board.

In a sixth embodiment of the present invention, there is provided a method of making a printed circuit board comprising providing a substrate, forming a plurality of electrically conductive traces on or near the substrate, forming a plurality of pads on the board, the pads approximately defining a surface mount device perimeter for each surface mount device that is to be mounted on the printed circuit board, and forming one or more weakened zones inside each surface mount perimeter. The method of the sixth embodiment of the present invention may further comprise at least one of forming one or more through-holes, forming one or more through-slots and forming one or more thinned portions, providing the surface mount device, dispensing an adhesive inside the surface mount perimeters, placing the surface mount device on the adhesive, curing the adhesive, and soldering the surface mount device to the printed circuit board.

Many combinations, adaptations, variations and permutations of the printed circuit board and surface mount device manufacturing, repair and removal methods, devices and elements disclosed herein may be made without departing from the scope of the present invention.

### BRIEF DESCRIPTION OF THE DRAWINGS

Numerous aspects of the various embodiments of the present invention will become apparent from the following specification, drawings and claims in which:

FIG. 1 shows a top view of one embodiment of a printed circuit board of the present invention;

FIG. 2 shows a bottom view of one embodiment of a printed circuit board of the present invention;

FIGS. 3(a) and 3(b) show a top view and corresponding cross-sectional view of one embodiment of a portion of a printed circuit board of the present invention;

FIGS. 4(a) and 4(b) show a top view and corresponding cross-sectional view of another embodiment of a portion of a printed circuit board of the present invention;

FIGS. 5(a) and 5(b) show a top view and corresponding cross-sectional view of yet another embodiment of a portion of a printed circuit board of the present invention;

FIGS. 6(a) and 6(b) show a top view and corresponding cross-sectional view of still another embodiment of a portion of a printed circuit board of the present invention;

FIGS. 7(a) and 7(b) show a top view and corresponding cross-sectional view of one alternative embodiment of a portion of a printed circuit board of the present invention;

FIGS. 8(a) and 8(b) show a top view and corresponding cross-sectional view of another alternative embodiment of a portion of a printed circuit board of the present invention;

FIG. 9 shows a flow diagram corresponding to one method of the present invention; and

FIG. 10 shows a flow diagram corresponding to another method of the present invention, and

FIG. 11 shows a flow diagram corresponding to yet another method of the present invention.

The drawings are not necessarily to scale. Like numbers refer to like parts or steps throughout the drawings.

### DETAILED DESCRIPTIONS

Set forth hereinbelow are detailed descriptions of some preferred embodiments of the present invention.

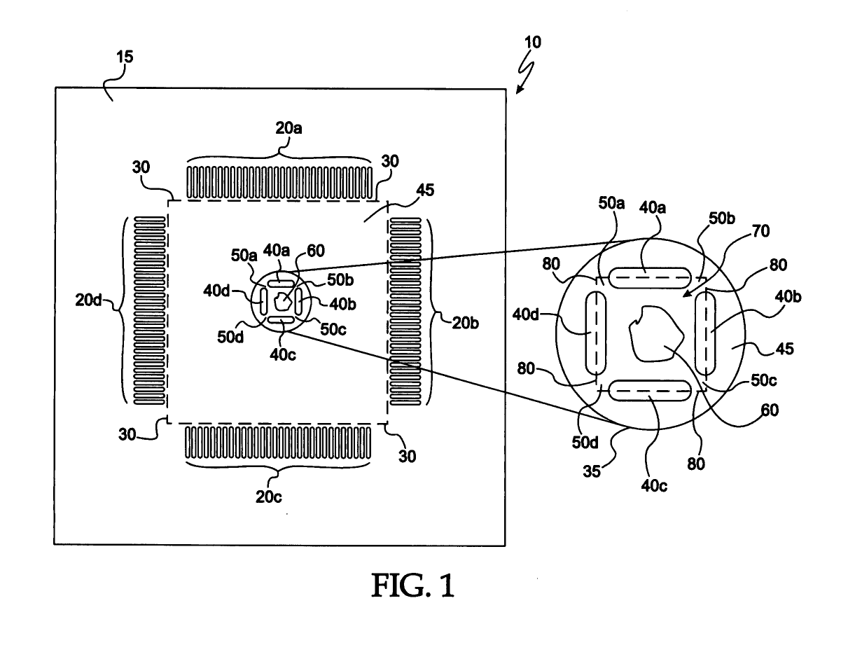

FIG. 1 shows top surface 15 of one embodiment of printed circuit board (“PCB”) 10 of the present invention. PCB 10 comprises a plurality of pads 20a through 20d configured to receive surface mount device contacts thereon. Pads 20a through 20d approximately define a surface mount device perimeter 30 on circuit board 10. That portion of PCB 10 located inside perimeter 30 is referred to herein as inside perimeter portion 45 (see FIG. 1). One or more weakened zones 40a through 40d are positioned inside surface mount device (“SMD”) perimeter 30. In the embodiment of the present invention shown in FIG. 1, zones 40a through 40d are slots that project all the way through board 10. Slots 40a through 40d are separated from one another by intervening PCB material 50a through 50d. Weakened zones 40a through 40d are configured to facilitate removal of a surface mount device (not shown in FIG. 1) from PCB 10 and inside perimeter portion 45 after the surface mount device has been attached to portion 70 with adhesive 60, discussed in further detail below.

Continuing to refer to FIG. 1, slots 40a through 40d are preferably situated sufficiently close to one another such that only thin tabs of intervening material 50a through 50d attach portion 70 of board 10 and inside perimeter portion 45 to the remainder of PCB 10. Portion 70 is located inside glue perimeter 80 (a perimeter defined by an imaginary line indicated by dashed lines in enlarged section 35 of FIG. 1). Glue perimeter 80 approximately follows or is otherwise near weakened zones 40a through 40d. Glue 60 is disposed on portion 70.

If an SMD glued to portion 70 with glue 60 is to be removed from PCB 10 and inside perimeter portion 45, intervening material portions 50a through 50d are cut or otherwise removed to permit the SMD to be removed from PCB 10 and inside perimeter portion 45 after the SMD's contacts or leads have been heated and the solder joining such contacts or leads to pads 20a through 20d has been removed. Portion 70 of PCB 10 and glue 60 remain attached to the SMD after the SMD has been removed from PCB 10 and inside perimeter portion 45. Note that enlarged section 35 in FIG. 1 shows details of portion 70.

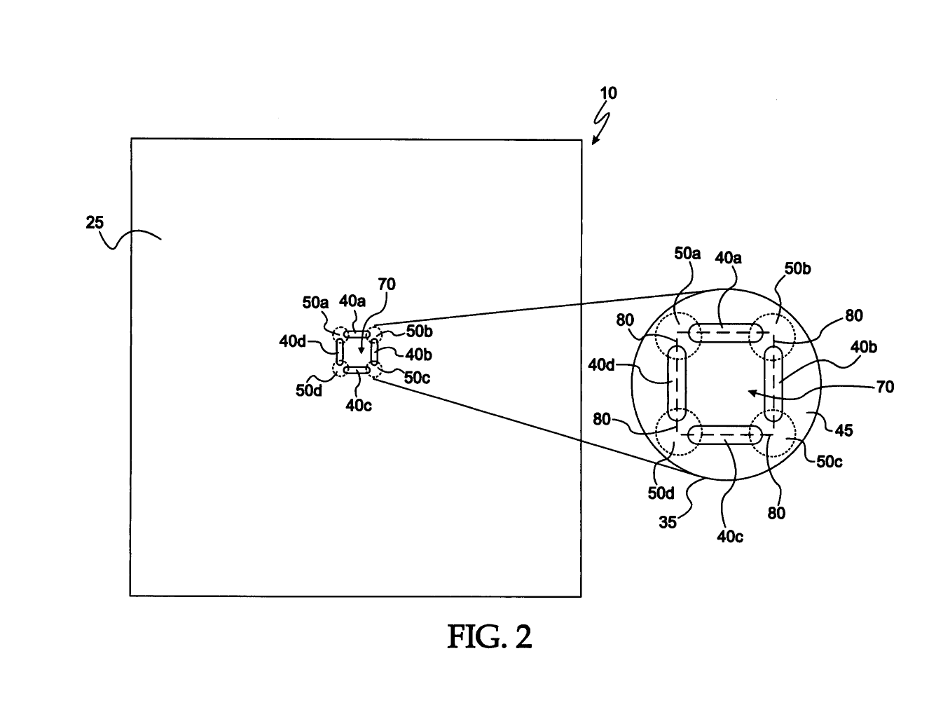

Referring now to FIG. 2, there is shown bottom side 25 of PCB 10 illustrated in FIG. 1. In a preferred method of the present invention, slots 40a through 40d are enlarged to form a continuous gap between portion 70 and inside perimeter portion 45 by cutting through intervening material 50a through 50d from bottom side 25 of PCB 10, the gap approximately following perimeter 80. The SMD glued to portion 70 may be freed from inside perimeter portion 45 after solder joining the contacts or leads of the SMD to pads 20a through 20d on top surface 15 of PCB 10 has been heated and removed. As discussed above respecting FIG. 1, portion 70 of inside perimeter portion 45 and glue 60 remain attached to the SMD after the SMD has been removed from inside perimeter portion 45. Enlarged section 36 in FIG. 2 shows further details of portion 70.

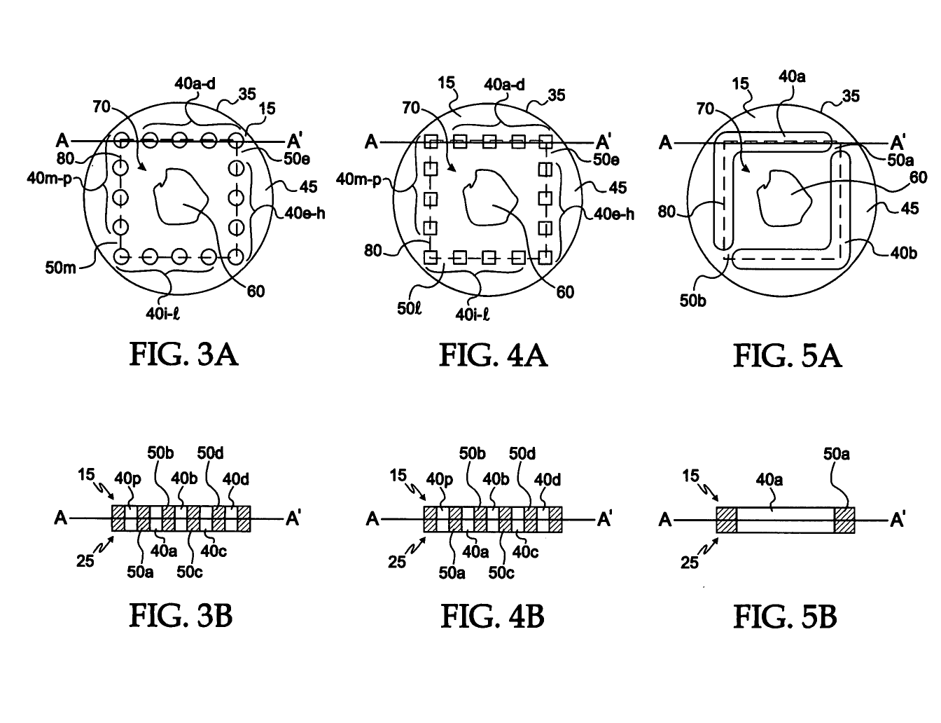

FIGS. 3(a) and 3(b) show a top view and corresponding cross-sectional view, respectively, of one embodiment of portion 70 of PCB 10 of the present invention. Enlarged section 35 in FIG. 3a shows through-holes 40a through 40p disposed near glue perimeter 80. Through-holes 40a through 40p are preferably situated sufficiently close to one another such that only thin tabs of intervening material 50a through 50p attach portion 70 to inside perimeter portion 45. Portion 70 is located inside glue perimeter 80 (a perimeter defined by an imaginary line indicated by dashed lines in enlarged section 35 of FIG. 3a). Glue perimeter 80 approximately follows or is near weakened zones 40a through 40p. Glue 60 is disposed on portion 70. Portion 70 in FIG. 3a may be removed from inside perimeter portion 45 using the same techniques described above respecting FIGS. 1 and 2. Referring now to FIG. 3b, there is a shown a cross-sectional view along line A-A′ of enlarged section 35 in FIG. 3a. FIG. 3b shows that the embodiment of the present invention illustrated in FIG. 3a features through-holes 40a through 40d that project through portion 70 between top surface 15 and bottom surface 25.

FIGS. 4(a) and 4(b) show a top view and corresponding cross-sectional view, respectively, of another embodiment of portion 70 of PCB 10 of the present invention. Enlarged section 35 in FIG. 4a shows through-slots 40a through 40p disposed near glue perimeter 80. Through-slots 40a through 40p are preferably situated sufficiently close to one another such that only thin tabs of intervening material 50a through 50p attach portion 70 to inside perimeter portion 45. Portion 70 is located inside glue perimeter 80 (a perimeter defined by an imaginary line indicated by dashed lines in enlarged section 35 of FIG. 4a). Glue perimeter 80 approximately follows or is near weakened zones 40a through 40p. Glue 60 is disposed on portion 70. Portion 70 in FIG. 4a may be removed from inside perimeter portion 45 using the same techniques described above respecting FIGS. 1 and 2. Referring now to FIG. 4b, there is a shown a cross-sectional view along line A-A′ of enlarged section 35 in FIG. 4a. FIG. 4b shows that the embodiment of the present invention illustrated in FIG. 4a features through-slots 40a through 40d that project through portion 70 between top surface 15 and bottom surface 25.

FIGS. 5(a) and 5(b) show a top view and corresponding cross-sectional view, respectively, of yet another embodiment of portion 70 of PCB 10 of the present invention. Enlarged section 35 in FIG. 5a shows through-slots 40a and 40b disposed near glue perimeter 80. Through-slots 40a and 40b are preferably situated sufficiently close to one another such that only thin tabs of intervening material 50a and 50b attach portion 70 to inside perimeter portion 45. Portion 70 is located inside glue perimeter 80 (a perimeter defined by an imaginary line indicated by dashed lines in enlarged section 35 of FIG. 5a). Glue perimeter 80 approximately follows or is near weakened zones 40a and 40b. Glue 60 is disposed on portion 70. Portion 70 in FIG. 5a may be removed from inside perimeter portion 45 using the same techniques described above respecting FIGS. 1 and 2. Referring now to FIG. 5b, there is a shown a cross-sectional view along line A-A′ of enlarged section 35 in FIG. 5a. FIG. 5b shows that the embodiment of the present invention illustrated in FIG. 5a features through-slot 40a that projects through portion 70 between top surface 15 and bottom surface 25.

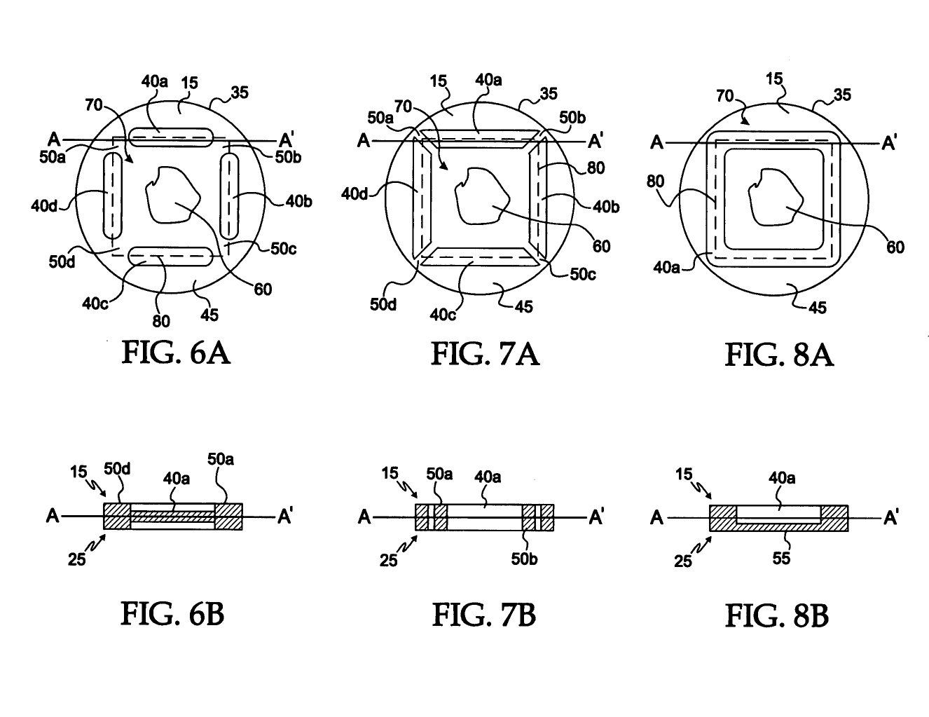

FIGS. 6(a) and 6(b) show a top view and corresponding cross-sectional view, respectively, of still another embodiment of portion 70 of PCB 10 of the present invention. Enlarged section 35 in FIG. 6a shows that weakened zones 40a through 40d are disposed near glue perimeter 80. Weakened zones 40a through 40d are preferably situated sufficiently close to one another such that, in addition to weakened zones/thinned portions 40a through 40d, only thin tabs of intervening material 50a through 50d attach portion 70 to inside perimeter portion 45. Portion 70 is located inside glue perimeter 80 (a perimeter defined by an imaginary line indicated by dashed lines in enlarged section 35 of FIG. 6a). Glue perimeter 80 approximately follows or is near weakened zones/thinned portions 40a through 40d. Glue 60 is disposed on portion 70. Portion 70 in FIG. 6a may be removed from inside perimeter portion 45 using techniques similar to those described above respecting FIGS. 1 and 2, with the exception that thinned portions 40a through 40d must also be cut through, otherwise removed (e.g., with a chemical solvent or catalyst), or mechanically broken. Referring now to FIG. 6b, there is a shown a cross-sectional view along line A-A′ of enlarged section 35 in FIG. 6a. FIG. 6b shows that the embodiment of the present invention illustrated in FIG. 6a features thinned portion 40a disposed between top surface 15 and bottom surface 25 of portion 70.

FIGS. 7(a) and 7(b) show a top view and corresponding cross-sectional view, respectively, of one alternative embodiment of portion 70 of PCB 10 of the present invention. Enlarged section 35 in FIG. 7a shows through-holes 40a through 40d disposed near glue perimeter 80. Through-holes 40a through 40d are preferably situated sufficiently close to one another such that only thin tabs of intervening material 50a through 50d attach portion 70 to inside perimeter portion 45. Portion 70 is located inside glue perimeter 80 (a perimeter defined by an imaginary line indicated by dashed lines in enlarged section 35 of FIG. 7a). Glue perimeter 80 approximately follows or is near weakened zones 40a through 40d. Glue 60 is disposed on portion 70. Portion 70 in FIG. 7a may be removed from inside perimeter portion 45 using the same techniques described above respecting FIGS. 1 and 2. Referring now to FIG. 7b, there is a shown a cross-sectional view along line A-A′ of enlarged section 35 in FIG. 7a. FIG. 7b shows that the embodiment of the present invention illustrated in FIG. 7a features through-hole 40a that projects through portion 70 between top surface 15 and bottom surface 25.

FIGS. 8(a) and 8(b) show a top view and corresponding cross-sectional view, respectively, of another alternative embodiment of portion 70 of PCB 10 of the present invention. Enlarged section 35 in FIG. 8a shows weakened zone 40 disposed near glue perimeter 80. In the embodiment of the present invention illustrated in FIGS. 8a and 8b, no thin tabs of intervening PCB material 50 are located in weakened zone 40a. Instead, weakened zone 40a is a gap that extends partially, but not completely, between top surface 15 and bottom surface 25. Portion 70 is located inside glue perimeter 80 (a perimeter defined by an imaginary line indicated by dashed lines in enlarged section 35 of FIG. 8a). Glue perimeter 80 approximately follows or is near weakened zone 40. Glue 60 is disposed on portion 70. Portion 70 in FIG. 8a may be removed from inside perimeter portion 45 using techniques similar to those described above respecting FIGS. 1 and 2. Referring now to FIG. 8b, there is a shown a cross-sectional view along line A-A′ of enlarged section 35 in FIG. 8a. FIG. 8b shows that the embodiment of the present invention illustrated in FIG. 8a features thinned material 40a.

Note that FIGS. 3a through 8b are not drawn to scale, and that some details typical of a PCB viewed in cross-section are not shown, such as, by way of example only, electrically conductive traces or vias disposed on or in PCB 10, PCB ground or power planes, information or markings that have been silk-screened or printed on PCB 1, fiducials, signal traces, or structural differentiation between a PCB substrate and other layers forming PCB 10 such as fiberglass, polyimide or epoxy.

Note that PCB 10 of the present invention typically, although not necessarily, includes a plurality of various electronic components mounted thereon, in addition to an SMD, the pads therefor and the one or more weakened zones. Additionally, and as noted above, the one or more weakened zones of the present invention are configured to facilitate removal of the surface mount device from the board after the surface mount device has been attached to the board with an adhesive or glue.

Note further that portion 70 may not contain electrically conductive traces for interconnecting electronic components mounted on or connected to PCB 10. Additionally, in the case where PCB 10 is a double-sided surface mount PCB, portion 70 must remain unobstructed on the bottom side of PCB 10; other components cannot be placed beneath portion 70. However, the footprint occupied by portion 70 and glue 60 is fairly small, and therefore the amount of surface area dedicated to the present invention on bottom surface 25 is negligible.

Some representative examples of SMDs suitable for use in the present invention include, but are not limited to, small-outline integrated circuits (SOICs), plastic leaded chip carriers (PLCCs), thin small-outline packages (TSOICs), shrink small-outline packages (SSOCPs), thin shrink small-outline packages (TSSOPs), quarter-size small-outline packages (QSOPs), very small outline packages (VSOPs), low-profile quad flat packages (LPQFPs), plastic quad flat-packages (PQFP), ceramic quad flat-packages (CQFPs), thin quad flat packages (TQFPs), quad flat packages (QFPs), power quad flat-packages (PQFPs), metric lead packages (MLPs) and metric quad flat packages (MQFPs).

Some representative examples of structures and materials suitable for use in PCBs of the present invention include, but are not limited to, PCBs containing electrically conductive layers separated and supported by layers of insulating material (i.e., substrates that have been laminated or glued together), PCBs containing layers electrically connected to one another by drilled holes or vias filled with an electrically conductive material, PCBs comprising blind and/or buried vias, and PCBs comprising one or more of phenolic resin, glass fiber, fiberglass, epoxy resin, epoxy, polyimide, polystyrene, cross-linked polystyrene, direct bonded copper substrates and insulated metal substrates.

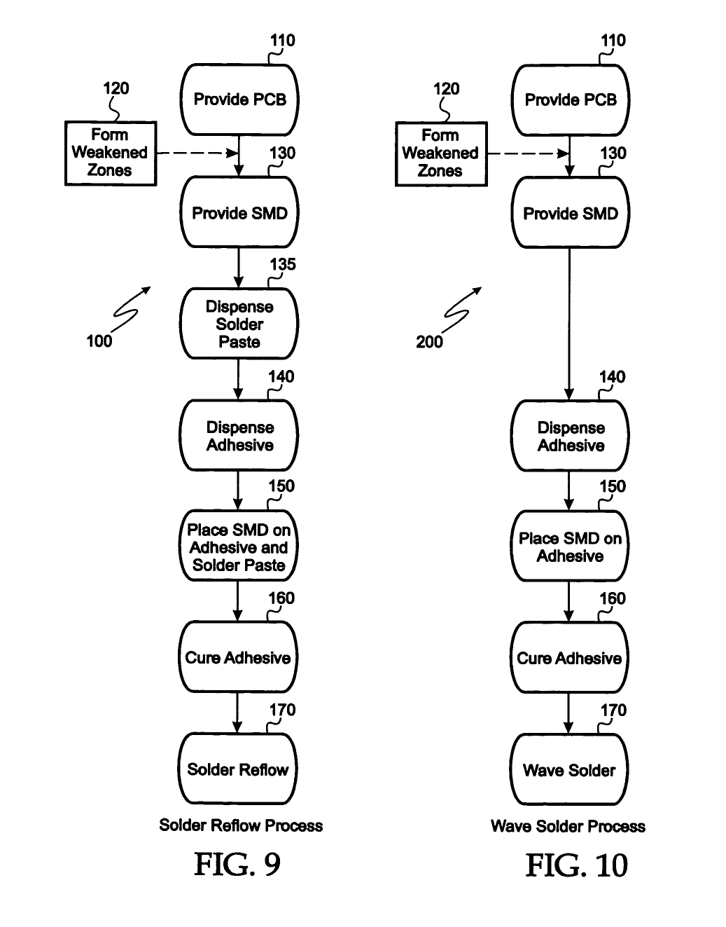

FIG. 9 shows one method 100 of the present invention that is particularly adapted to a solder reflow process, such as an infrared, convection or vapor phase reflow process. In step 110, PCB 10 is provided, preferably with one or more weakened zones 40 already having been formed inside surface mount device perimeter 30 of PCB 10 as part of the PCB manufacturing process. In optional step 120, however, the one or more weakened zones 40 may be formed or modified in PCB 10 after PCB has been provided. In accordance with the descriptions set forth herein and illustrated in FIGS. 1 through 8b, one or more weakened zones 40 may be provided by forming one or more slots, holes and/or thinned portions, and other types of weakened zones amenable to laser treatment, cutting, abrading, removal, melting, breaking or other suitable methods. As shown in FIG. 9, method 100 preferably comprises one or more of providing the PCB with the one or more weakened zones having already been formed, providing the SMD, dispensing solder paste, dispensing adhesive, placing the SMD on the adhesive and the solder paste and gluing the SMD to portion 70 of PCB 10, and soldering contacts or leads of the SMD to corresponding solder pads disposed on PCB 10 using a solder reflow process or other suitable technique.

FIG. 10 shows one method 200 of the present invention particularly adapted to a wave solder process. In step 110, PCB 10 is provided, preferably with one or more weakened zones 40 already having been formed inside surface mount device perimeter 30 of PCB 10 as part of the PCB manufacturing process. In optional step 120, however, the one or more weakened zones 40 may be formed or modified in PCB 10 after PCB has been provided. In accordance with the descriptions set forth herein and illustrated in FIGS. 1 through 8b, one or more weakened zones 40 may be provided by forming one or more slots, holes and/or thinned portions, and other types of weakened zones amenable to laser treatment, cutting, abrading, removal, melting, breaking or other suitable methods. As shown in FIG. 10, method 200 preferably comprises one or more of providing the PCB with the one or more weakened zones having already been formed, providing the SMD, dispensing adhesive, placing the SMD on the adhesive and gluing the SMD to portion 70 of PCB 10, and soldering contacts or leads of the SMD to corresponding solder pads disposed on PCB 10 using a wave solder process or other suitable technique.

Gluing in methods 100 and 200 may be effected using any of a number of suitable methods well known in the printed circuit board arts. Glues such as cyanoacrylate, epoxy, high temperature epoxy, LOCTITE, acrylic adhesives and other suitable adhesives may be employed, depending on the particular manufacturing method that is to be used. Adhesive dispensing may be accomplished using well known syringe, needle or nozzle dispensing techniques, or by using pin transfer, drop placement, stencil printing or other suitable techniques. Depending on the PCB manufacturing process that has been selected and the adhesive that is to be used, glue 60 may need to be cured or heated after glue 60 has been dispensed on portion 70 and the SMD has been placed thereon.

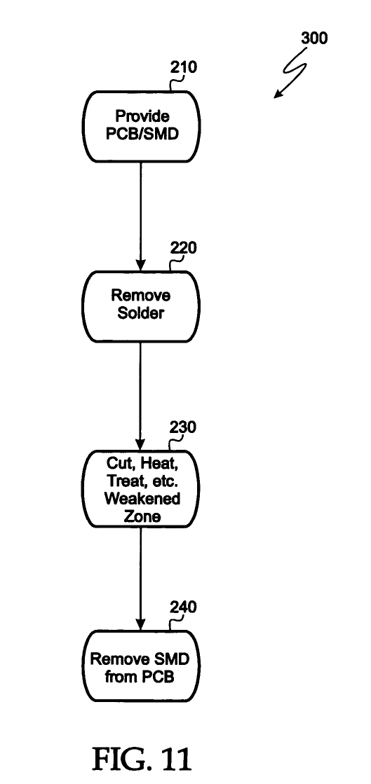

FIG. 11 shows another method 300 of the present invention for removing a surface mount device from a printed circuit board. In method 300, a surface mount device has been glued and soldered to PCB 10, and PCB 10 comprises one or more weakened zones located inside surface mount perimeters 30 corresponding approximately to the outlines of the surface mount device. Method 300 preferably comprises removing solder connecting surface mount device contacts to pads located on the printed circuit board, and then at least one of abrading, cutting, scribing, drilling, sawing, scoring, cutting, laser cutting or weakening, laser etching, applying one or more chemical solvents, applying one or more suitable chemical catalysts, treating and etching the weakened zones to facilitate release of the surface mount device from the printed circuit board.

Solder removal may be effected using any of a number of suitable methods well known in the printed circuit board arts such as thermal heating followed by suctioning of melted solder. Desoldering techniques, tools and materials suitable for use in the present invention include, but are not limited to, desoldering braids, heat guns, vacuum plungers (solder suckers), removal alloys, removal fluxes, and/or vacuum and/or pressure pumps with specialized heater tips and nozzles

Abrading and cutting methods suitable for use in the present invention include, but are not limited to, scribing, drilling, sawing, scoring, cutting, laser cutting or weakening, cutting, and abrading, such abrading and cutting methods being applied to the one or more weakened zones in an appropriate manner. Treating or etching methods suitable for use in the present invention include, but are not limited to, laser application, applying one or more suitable chemical solvents, etching, applying one or more suitable chemical catalysts, such treating or etching methods being applied to the one or more weakened zones in an appropriate manner.

In another method of the present invention, there is provided a suitable PCB substrate. A plurality of electrically conductive traces and/or vias are formed on the substrate or another portion of the PCB. A plurality of pads are formed on the board, the pads defining an approximate surface mount device perimeter 30. Weakened zones are formed inside surface mount perimeter 30.

In still another method of the present invention, portion 70 remains glued to the bottom of the removed SMD, which in most cases will not pose any significant problems. For example, in the case where a failed SMD is being replaced, the continued adherence of portion 70 to the underside of the failed and removed SMD (which will be disposed of anyway) makes no difference. In the context of SMD failure analysis, the removed SMD may be placed in a socket which includes a cavity to accept portion 70 attached to the SMD. Certain failure analysis is destructive and includes removing a portion of the integrated circuit material to provide access to the internal integrated circuit die. Such packaging material removal is not impeded by portion 70 remaining attached to the underside of the SMD.

Many different combinations, variations, adaptations and permutations may be made respecting the methods illustrated and described herein, and yet nevertheless fall within the scope of the present invention. For example, while methods 100 and 200 illustrated in FIGS. 9 and 10 are particularly adapted to solder reflow and wave solder processes, the methods of the present invention are not limited to such techniques, and include within their scope other suitable methods well known in the printed circuit board arts such as using an infrared lamp, using a point source such as an electric soldering iron, a brazing torch or a hot-air soldering tool. Also by way of example, laser scribing may be combined with abrading to remove an SMD and portion 70 from PCB 10. Additionally, various steps in the methods of the present invention may be combined or modified, the order in which at least some steps are performed may be changed, or some steps may be eliminated entirely.

Having read and understood the present disclosure, those skilled in the art will now understand that many combinations, adaptations, variations and permutations of known printed circuit board and surface mount device manufacturing methods and structures may be employed successfully within the scope of the present invention. Accordingly, the preceding specific embodiments are illustrative of the practice of the invention. It is to be understood, therefore, that other expedients known to those skilled in the art or disclosed herein may be employed without departing from the invention or the scope of the appended claims.

In the claims, means plus function clauses are intended to cover the structures described herein as performing the recited function and their equivalents. Means plus function clauses in the claims are not intended to be limited to structural equivalents only, but are also intended to include structures which function equivalently in the environment of the claimed combination.

All printed publications and patents referenced hereinabove are hereby incorporated by referenced herein, each in its respective entirety.

1. A printed circuit board comprising:
a board having a surface;
a pad located on the surface and configured to receive at least one contact of a surface mount device thereon;
a weakened zone being positioned inside a perimeter of the board;
the zone being configured to facilitate removal of the surface mount device from the board after the surface mount device has been attached to the board with an adhesive.

2. The printed circuit board of claim 1, wherein the weakened zone is selected from the group consisting of one or more through-holes, one or more through-slots and one or more thinned portions.

3. (canceled)

4. The printed circuit board of claim 1, wherein the surface mount device is selected from the group consisting of one or more SOICs, PLCCs, TSOICs, SSOCPs, TSSOPs, QSOPs, VSOPs, LPQFPs, PQFPs, CQFPs, TQFPs, QFPs, PQFPs, MLPs and MQFPs.

5. The printed circuit board of claim 1, wherein the adhesive is disposed between the surface mount device and the board.

6. The printed circuit board of claim 1, wherein the adhesive is selected from the group consisting of cyanoacrylate, epoxy, high temperature epoxy, the adhesive sold under the trademark LOCTITE and acrylic adhesive.

7. A printed circuit board having an electronic component mounted thereon, the printed circuit board comprising:
a board having a surface;
a pad located on the surface and configured to receive at least one contact of a surface mount device thereon;
a weakened zone being positioned inside a perimeter of the board;
the zone being configured to facilitate removal of the surface mount device from the board after the surface mount device has been attached to the board with an adhesive.

8. The printed circuit board of claim 7, wherein the zone is selected from the group consisting of one or more through-holes, one or more through-slots and one or more thinned portions.

9. (canceled)

10. The printed circuit board of claim 7, wherein the surface mount device is selected from the group consisting of one or more SOICs, PLCCs, TSOICs, SSOCPs, TSSOPs, QSOPS, VSOPs, LPQFPs, PQFPs, CQFPs, TQFPS, QFPS, PQFPs, MLPs and MQFPs.

11. The printed circuit board of claim 7, wherein the adhesive is being disposed between the surface mount device and the board.

12. The printed circuit board of claim 7, wherein the adhesive is selected from the group consisting of cyanoacrylate, epoxy, high temperature epoxy, the adhesive sold under the trademark LOCTITE and acrylic adhesive.

13. An electronic device comprising:
an electronic component;
a printed circuit board to which the electronic component is mounted, the printed circuit board comprising:
a pad configured to receive at least one contact of a surface mount device thereon;
a weakened zone being positioned inside a perimeter;
the zone being configured to facilitate removal of the surface mount device from the board after the surface mount device has been attached to the board with an adhesive.

14. The electronic device of claim 13, wherein the weakened zone is selected from the group consisting of one or more through-holes, one or more through-slots and one or more thinned portions.

15. (canceled)

16. The electronic device of claim 13, wherein the surface mount device is selected from the group consisting of one or more SOICs, PLCCs, TSOICs, SSOCPs, TSSOPs, QSOPs, VSOPs, LPQFPs, PQFPs, CQFPs, TQFPs, QFPs, PQFPs, MLPs and MQFPs.

17. The electronic device of claim 13, wherein the adhesive is disposed between the surface mount device and the board.

18. The electronic device of claim 13, wherein the adhesive is selected from the group consisting of cyanoacrylate, epoxy, high temperature epoxy, the adhesive sold under the trademark LOCTITE and acrylic adhesive.

19. A method of forming a weakened zone in a printed circuit board to facilitate removal of a surface mount device adhered to the printed circuit board, comprising:
(a) providing the printed circuit board, and
(b) forming a weakened zone in the printed circuit board inside a surface mount device perimeter of the printed circuit board, the weakened zone facilitating removal of a surface mount device attached via an adhesive to the printed circuit board within the surface mount device perimeter.

20. The method of claim 19, wherein the forming the weakened zone further comprises a process selected from the list consisting of forming one or more through-holes, forming one or more through-slots and forming one or more thinned portions.

21. (canceled)

22. The method of claim 19, further comprising dispensing the adhesive inside the surface mount device perimeter.

23. The method of claim 22, further comprising placing the surface mount device on the adhesive.

24. The method of claim 23, further comprising curing the adhesive.

25. The method of claim 23, further comprising soldering the surface mount device to the printed circuit board.

26. A method of facilitating removal of a surface mount device that has been adhered and soldered to a printed circuit board, the printed circuit board comprising a weakened zone located inside a surface mount perimeter corresponding approximately to the outlines of the surface mount device, the method comprising:
(a) removing solder connecting surface mount device contacts to pads located on the printed circuit board, and
(b) at least one of abrading, cutting, scribing, drilling, sawing, scoring, cutting, laser cutting, laser weakening, laser etching, applying one or more chemical solvents, applying one or more suitable chemical catalysts, treating and etching one or more areas of the printed circuit board adjacent the weakened zone to facilitate release of the surface mount device from the printed circuit board.

27. The method of claim 26, further comprising removing the surface mount device from the printed circuit board.

28. A method of making a printed circuit board, comprising:
(a) providing a substrate;
(b) forming an electrically conductive trace on or near the substrate;
(c) forming a pad on the substrate; and
(d) forming a weakened zone inside a surface mount device perimeter of a surface of the substrate, the weakened zone facilitating removal of a surface mount device attached via an adhesive to the substrate within the surface mount device perimeter.

29. The method of claim 28, wherein the forming a weakened zone further comprises a process selected from the list consisting of forming one or more through-holes, forming one or more through-slots and forming one or more thinned portions.

30. (canceled)

31. The method of claim 28, further comprising dispensing the adhesive inside the surface mount device perimeter.

32. The method of claim 31, further comprising placing the surface mount device on the adhesive.

33. The method of claim 32, further comprising curing the adhesive.

34. The method of claim 32, further comprising soldering the surface mount device to the pad.

35. The printed circuit board of claim 1, further comprising a second pad configured to receive a second contact of the surface mount device, wherein the pad and the second pad define the perimeter, the weakened zone being positioned inside the perimeter.

36. The printed circuit board of claim 1, wherein the board comprises a second surface spaced from and opposite the surface and wherein the weakened zone is defined by an opening that projects through the surface and the second surface of the board, wherein the opening has a cross-sectional shape as viewed along an axis perpendicular to the surface that is selected from the group consisting of a circular-like shape, a rectangular-like shape, an L-shape and a trapezoidal-like shape.

37. The printed circuit board of claim 1, wherein the board comprises a second surface spaced from and opposite the surface and wherein the weakened zone is defined by an opening that projects through the surface but not through the second surface, wherein the opening defines a rectangular path in the surface.

38. The printed circuit board of claim 1, further comprising a second zone being positioned inside the perimeter and adjacent to the zone, wherein a thin tab of material of the board is located between the zone and the second zone.

39. The printed circuit board of claim 1, further comprising a second zone positioned in the perimeter, wherein the second zone and the zone define at least in part an adhesive perimeter of an area of the first surface onto which the adhesive is applied.

40. The printed circuit board of claim 39, wherein there are no electrical components on the second surface and within an area of the second surface defined by the adhesive perimeter.

41. The printed circuit board of claim 7, further comprising a second pad configured to receive a second contact of the surface mount device, wherein the pad and the second pad define the perimeter, the weakened zone being positioned inside the perimeter.

42. The printed circuit board of claim 7, wherein the board comprises a second surface spaced from and opposite the surface and wherein the weakened zone is defined by an opening that projects all the way through the surface and the second surface of the board, wherein the opening has a cross-sectional shape as viewed along an axis perpendicular to the surface that is selected from the group consisting of a circular-like shape, a rectangular-like shape, an L-shape and a trapezoidal-like shape.

43. The printed circuit board of claim 7, wherein the board comprises a second surface spaced from and opposite the surface and wherein the weakened zone is defined by an opening that projects through the surface but not through the second surface, wherein the opening defines a rectangular path in the surface.

44. The printed circuit board of claim 7, further comprising a second zone being positioned inside the perimeter and adjacent to the zone, wherein a thin tab of material of the board is located between the zone and the second zone.

45. The printed circuit board of claim 7, further comprising a second zone, wherein the second zone and the zone define at least in part an adhesive perimeter of an area of the surface onto which the adhesive is applied.

46. The printed circuit board of claim 45, wherein there are no electrical components on the second surface and within an area of the second surface defined by the adhesive perimeter.

47. The electronic device of claim 13, the printed circuit board further comprising a second pad configured to receive a second contact of the surface mount device, wherein the pad and the second pad define the perimeter, the weakened zone being positioned inside the perimeter.

48. The electronic device of claim 13, wherein the weakened zone is defined by an opening that projects through the printed circuit board, wherein the opening has a cross-sectional shape as viewed along an axis perpendicular to a surface of the printed circuit board to which the surface mount device is mounted that is selected from the group consisting of a circular-like shape, a rectangular-like shape, an L-shape and a trapezoidal-like shape.

49. The electronic device of claim 13, wherein the weakened zone is defined by an opening that projects through a first surface of the printed circuit board but not through a second surface of the printed circuit board that is spaced from and opposite the first surface, wherein the opening defines a rectangular path in the first surface.

50. The electronic device of claim 13, wherein the printed circuit board further comprises a second zone being positioned inside the perimeter and adjacent to the zone, wherein a thin tab of material of the board is located between the zone and the second zone.

51. The electronic device of claim 13, wherein the printed circuit board further comprises a second zone, wherein the second zone and the zone define at least in part an adhesive perimeter of an area of a surface of the printed circuit board onto which the adhesive is applied.

52. The electronic device of claim 51, wherein on a second surface of the printed circuit board that is spaced from and opposite the surface there are no electrical components within an area of the second surface defined by the adhesive perimeter.

53. The method of claim 19, wherein the printed circuit board lacks electrical components on a second surface of the printed circuit board that is spaced from and opposite to a first surface of the printed circuit board to which the surface mount device is adhered.

54. The method of claim 26, wherein release of the surface mount device results in a portion of the printed circuit board being removed from the printed circuit board while still being attached to the surface mount device.

55. The method of claim 28, wherein the substrate lacks electrical components on a second surface of the substrate that is spaced from and opposite to a first surface of the substrate to which the surface mount device is adhered.

56. A printed circuit board comprising:
a means for providing an electrical connection to a surface mount device;
a means for supporting the pad and the surface mount device and for facilitating removal of the surface mount device, wherein the surface mount device is attached to the means for supporting via an adhesive.

57. The printed circuit board of claim 56, wherein the surface mount device is selected from the group consisting of one or more SOICs, PLCCs, TSOICs, SSOCPs, TSSOPs, QSOPs, VSOPs, LPQFPs, PQFPs, CQFPs, TQFPs, QFPs, PQFPs, MLPs and MQFPs.

58. The printed circuit board of claim 56, wherein the adhesive is disposed between the surface mount device and the means for supporting the pad and surface mount device.

59. The printed circuit board of claim 56, wherein the adhesive is selected from the group consisting of cyanoacrylate, epoxy, high temperature epoxy, the adhesive sold under the trademark LOCTITE and acrylic adhesive.

60. The printed circuit board of claim 56, further comprising an electronic component mounted on the means for supporting the pad and the surface mount device.
